(19) United States
(12) Patent Application Publication
(10) Pub. No.: US 2008/0018959 A1
(43) Pub. Date: Jan. 24, 2008

(54) Multiplier And Image Sensor Employing Same

(76) Inventors: Kazuaki Sawada, Aichi (JP); Yuki Maruyama, Aichi (JP)

Correspondence Address: Matthew K. Ryan;Frommer Lawrence & Haug, 745 Fifth Avenue, New York, NY, 10151, US

(21) Appl. No.: 11/793,619

(22) PCT Filed: Dec. 20, 2005
(86) PCT No.: PCT/JP05/23310

§ 371 Date: Jun. 19, 2007

(30) Foreign Application Priority Data
Dec. 21, 2004 (JP) 2004-369896

(51) Int. Cl. H01L 27/148; H04N 1/04

(52) U.S. Cl. 358/482; 257/229; 257/E27.15

(57) ABSTRACT

charge generated by the incident light is accumulated in a charge accumulation well in the semiconductor substrate immediately beneath the first electrode film when the gate voltage applied to the first electrode film is a first gate voltage, and the accumulated charge is amplified when the gate voltage is a second gate voltage.

### TECHNICAL FIELD

The invention relates to a charge accumulating and amplifying device and an image sensor using the same.

### BACKGROUND ART

Solid-state devices of a carrier amplifying system are widely sold on market, and they are called electron avalanche photodiodes (APD) and are applied also as area image sensors.

Other devices are designed to amplify the electric charge by inducing collision ionization of a charge carrier in CCD transfer route (amplifying unit) by employing CCD system (see Patent documents 1 and 2).

Refer also to Patent document 3 as a document relating to the invention.

Patent document 1: Japanese Patent Application Laid-Open (JP-A) No. 7-176721

Patent document 2: JP-A No. 10-30426

Patent document 3: JP-A No. 10-332423

### DISCLOSURE OF THE INVENTION

### Problems to be Solved by the Invention

An APD system device is too large to be assembled in a pixel array, and is limited in the amplifying gain. The device of CCD system requires an amplifying unit aside from the image sensor array, and is hence increased in the device size.

Also, the charge cannot be amplified in each pixel. Hence, the above-described amplifying unit cannot be provided in an image sensor (for example, CMOS image sensor) of a type in which the charge generated in one pixel is accumulated in the accumulation well corresponding to the pixel, and the charge in the accumulation well is directly read out and processed.

It is hence an object of the invention to amplify the charge in every pixel without providing with any amplifying unit.

### Means for Solving the Problems

A first aspect of the invention is intended to solve the above problems, and relates to a charge accumulating and amplifying device comprising:

a semiconductor substrate,

a first electrode film formed on the semiconductor substrate being intervened an insulating film between the first electrode file and semiconductor substrate, for transmitting incident light and receiving a gate voltage, a second electrode film adjacent to the first electrode film, and

a diffusion layer adjacent to the second electrode film,

wherein a charge generated by the incident light is accumulated in a charge accumulation well in the semiconductor substrate immediately beneath the first electrode film when the gate voltage applied to the first electrode film is a first gate voltage, and the accumulated charge is amplified when the gate voltage is a second gate voltage.

According to the first aspect of the invention having such configuration, while the first gate voltage is applied to the first electrode film, the charge generated through the first electrode film for composing a photo detector of a pixel is accumulated in the accumulation well of the semiconductor substrate immediately beneath the first electrode film.

When the voltage applied to the first electrode film is the second gate voltage, the electric field applied to the accumulation well layer is changed, and hence the accumulation well is increased in depth. As a result, when the charge moves to the bottom of the accumulation well, a collision ionization phenomenon is induced, and the charge is amplified. When the charge is thus amplified, no particular amplifying unit is needed. Hence the device is reduced in size.

Besides, in the CMOS type image sensor, the charge can be amplified in each pixel.

By moving the charge physically, collision between the charge and crystal lattice occurs. As a result, the collision ionization phenomenon is induced, and the charge is amplified securely.

In a second aspect of the invention, the amplification factor of charge is adjusted by adjusting the ratio of the first gate voltage and second gate voltage.

The charge amplification factor varies with the magnitude of energy gap of the depth of an accumulation well (bottom energy level) in a charge accumulation state and the depth of an accumulation well in a charge amplification state. The larger the energy gap of the two is, the charges collide with a greater impact force, and the larger the amplification factor is. Herein, the depth of an accumulation well in a charge accumulation state is defined by the first gate voltage, and the depth of an accumulation well in a charge amplified state is defined by the second gate voltage. Therefore, by adjusting the ratio of both voltages, the amplification factor can be adjusted.

In a third aspect of the invention, by adjusting the number of times of repeated applications of the first gate voltage and the second gate voltage, the charge amplification factor is adjusted.

When application of the first gate voltage and the second gate voltage to the first electrode film is repeated, collision of the charge is also repeated on every occasion of repetition. Hence, the amplification factor is raised when the number of times of repetition is increased.

In a fourth aspect of the invention, the semiconductor substrate is a p type silicon semiconductor substrate, and the diffusion layer is an n+ type diffusion layer.

By employing such configuration, electrons can be amplified.

In a fifth aspect of the invention, the first electrode film is formed of a polycrystalline silicon film doped with an impurity.

By employing such configuration, the device can be manufactured in a general semiconductor manufacturing process.

A sixth aspect of the invention is defined as follows. That is:

By lowering the voltage applied to the second electrode film, the charge in the charge accumulation well is transferred to the diffusion layer, and can be read out from the diffusion layer.

The charge accumulating and amplifying device having such configuration can be assembled in an image sensor.

The charge accumulating and amplifying device defined in the first to sixth aspects of the invention is preferably used in an image sensor in which the charge generated in one pixel is accumulated in the accumulation well corresponding to the pixel, and the charge in the accumulation well is directly read out and signal-processed.

The location of accumulation well is not limited particularly to immediately beneath the first electrode film, but the well may be present in any one of unit devices for composing the pixel. Direct reading of amplified charge in the accumulation well means that the charge is not further amplified in the image sensor. Therefore, the charge amplified in the accumulation well may be once accumulated in other well, and the charge may be read out from this well.

In the substrate, the portion composing the accumulation well may be doped with an impurity.

According to the studies by the inventors, by doping the surface of the accumulation well with an impurity of a conductive type different from the conductive type of the accumulation well, the location of the charge in the accumulation well is moved to a deeper position from the surface. When the electric field to be applied to the accumulation well is changed, due to the change of the electric field, the charge is moved to the surface side of the accumulation well (the position of the charge is changed physically), and collides against the lattice for forming the accumulation well. As a result, the collision ionization is induced securely, and the charge amplification is increased.

The charge amplification in the photo detecting device is explained so far, and the invention can be applied to all semiconductor devices having an accumulation well layer for accumulating the charge. For example, in a semiconductor device having a well layer composed so as to change the depth corresponding to the magnitude of a physical or chemical amount, the charge is accumulated in the well layer, and the electric field applied to the well layer is changed, and the charge collision ionization phenomenon is induced in the well layer, and hence the charge can be amplified. The physical amount is, for example, the quantity of light of infrared ray or the like, the quantity of sound wave, the quantity of electromagnetic wave, and the temperature. The chemical amount is, for example, the ion concentration such as pH, and the molecular concentration.

In the invention, the charge means an electron or a hole. When amplifying the electron, a p type silicon semiconductor substrate may be used as in the fourth aspect of the invention. When charge collision occurs on the silicon substrate, the electrons are collected in the bottom of the accumulation well by the function of electric field. On the other hand, holes flow out to the substrate side of the silicon substrate, and the holes are no longer related to collision. As the substrate for electron amplification, aside from silicon, amorphous silicon, polycrystalline silicon or the like may be used.

When holes are amplified as the charge, an n type Si substrate may be used. In a selenium substrate, when charge collision occurs, the holes are collected in the bottom of the accumulation well by the electric field (in reverse direction in the case of the silicon substrate). On the other hand, since the electrons flow to the interface side of the selenium substrate, the electrons are no longer related to collision. As the substrate for hole amplification, a selenium material may be used.

### BRIEF DESCRIPTION OF THE DRAWINGS

FIG. 1 is a sectional view of a charge accumulating and amplifying device in an embodiment of the invention.

FIG. 2 shows a potential distribution in an accumulation well when Vg is a first gate voltage applied to a first electrode film.

FIG. 3 shows a potential distribution in an accumulation well when Vg is a second gate voltage applied to a first electrode film.

FIG. 4 shows an electric field distribution in an accumulation well when Vg is a second gate voltage applied to a first electrode film.

FIG. 5 is a timing diagram showing the charge accumulating and amplifying operation.

FIG. 6 is a schematic diagram of a two-dimensional potential distribution in a charge accumulating process and a charge amplifying process in an accumulation well of the charge accumulating and amplifying device.

FIG. 7 is a graph of simulation results when amplified once and when not amplified, in the case of constant illumination with light of wavelength of 550 nm and light intensity of 1×10⁻⁸ W/cm², in a charge accumulating and amplifying area of 25×10⁻⁸ cm².

FIG. 8 is a graph of simulation results when amplified five times, in the case of constant illumination with light of wavelength of 550 nm and light intensity of 1×10⁻⁸ W/cm², in a charge accumulating and amplifying area of 25×10⁻⁸ cm².

FIG. 9 is a graph showing the relation of the charge amplification factor M and the second gate voltage.

FIG. 10 is a block diagram of CMOS image sensor assembling a charge accumulating and amplifying device of an embodiment in each pixel.

FIG. 11(A) is a sectional view of a charge accumulating and amplifying device in other embodiment, and (B) is a diagram of a potential distribution in lateral direction (X direction) and depth direction (Z direction) in an accumulation well immediately beneath the first electrode film 5 in the charge accumulating and amplifying device.

FIG. 12 shows a profile of a charge accumulation well in a second embodiment, in which (A) shows the impurity concentration, (B) shows the potential distribution of the charge accumulation well when the gate voltage is 5 V, and (C) shows the potential distribution of the charge accumulation well when the gate voltage is 12 V.

FIG. 13 schematically expresses collision of the charge occurring due to change in a potential distribution in an accumulation well layer.

FIG. 14 shows the relation of the charge amplification factor and the applied gate voltage in the second embodiment.

### BEST MODE FOR CARRYING OUT THE INVENTION

### Embodiment 1

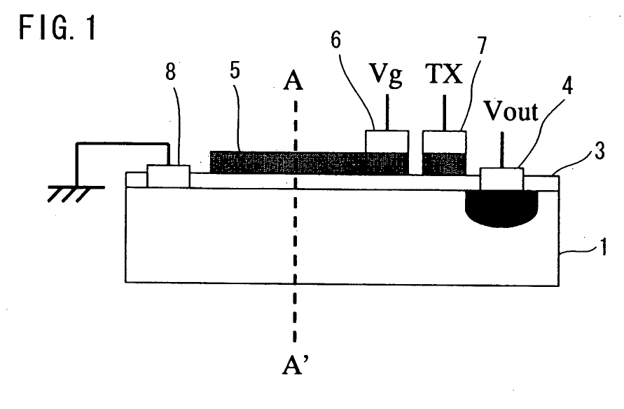

FIG. 1 is a sectional view of the device of the invention. In FIG. 1, reference numeral 1 is a p type silicon substrate, 2 is an n+ type diffusion layer formed in the p type silicon substrate, 3 is a silicon oxide film (SiO₂) formed on the p type silicon substrate 1, 4 is an Al electrode connected to the n+ type diffusion layer 2, 5 is a polycrystalline silicon film (poly-Si) formed on the silicon oxide film 3 and doped with an impurity, and 6 is a gate electrode connected to the polycrystalline silicon film 5, and the polycrystalline silicon film 5 functions as a first electrode film for transmitting the light through the silicon film 3. Reference numeral 7 is a transfer electrode (a second electrode film) for transferring the electron amplified beneath the polycrystalline silicon film 5 doped with an impurity to the n+ type diffusion layer 2, and 8 is an electrode connected to the p type silicon substrate 1, and grounded.

The structure shown in FIG. 1 is formed by a known manufacturing method of a semiconductor device.

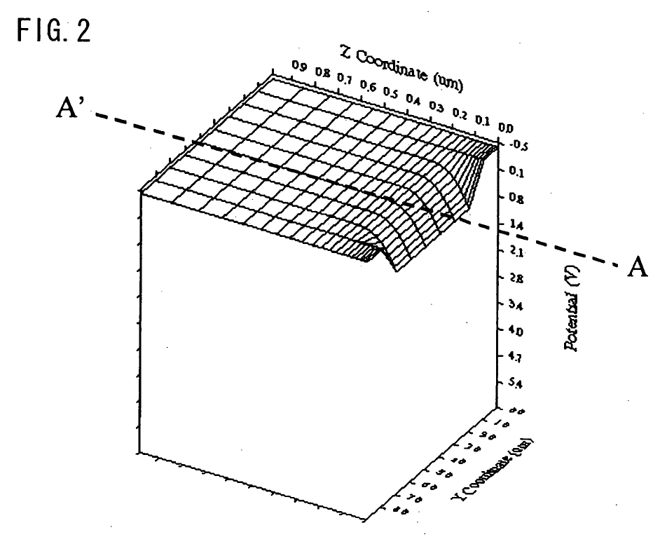

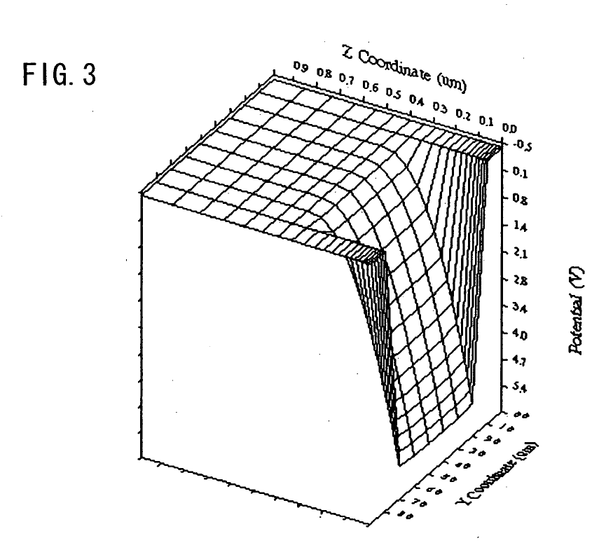

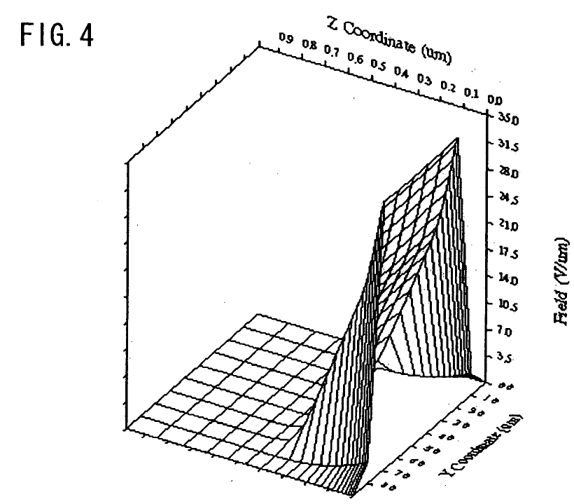

FIG. 2 and FIG. 4 are characteristic diagrams of the charge accumulating and amplifying device in FIG. 1, and specifically FIG. 2 shows the potential distribution when a gate voltage Vg is a first gate voltage (2 V) (charge capturing, accumulating), and FIG. 3 shows the potential distribution when a gate voltage Vg is a second gate voltage (10 V) (charge amplifying).

FIG. 4 is a characteristic diagram of the charge accumulating and amplifying device in FIG. 1, showing the electric field distribution when a gate voltage Vg is a second gate voltage (10 V) (charge amplifying). In the silicon substrate 1, an electric field for inducing electron collision ionization significantly is 3×10⁵ V/cm or more, and in FIG. 4, the surface electric field at a second gate voltage is 35 V/μm (3.5×10⁵ V/cm), and it is known that collision ionization occurs sufficiently.

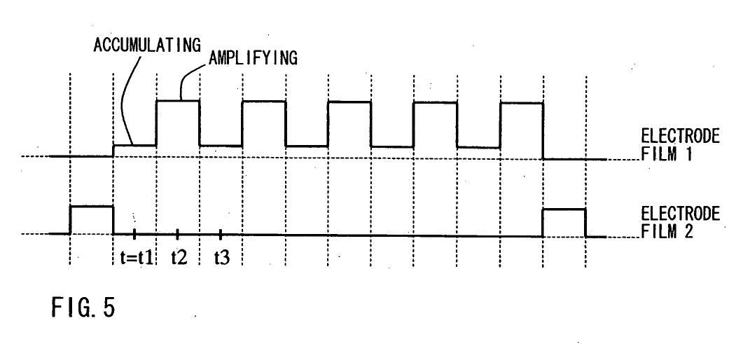

FIG. 5 is a timing diagram of a charge accumulating and amplifying operation in the invention. FIG. 5 shows five times of amplifying.

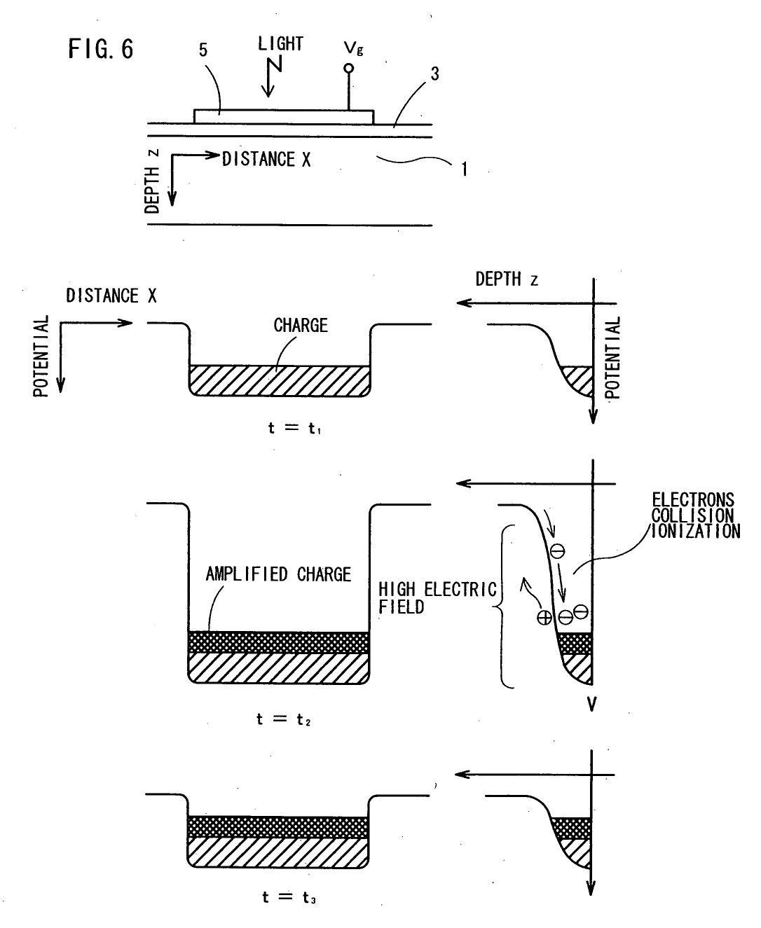

FIG. 6 shows a potential distribution in lateral direction (X direction) and depth direction (Z direction) in an accumulation well immediately beneath the first electrode film 5 in the charge accumulating and amplifying device of the invention.

An accumulation well preliminarily biased by direct current at a first gate voltage (2 V) is formed in the p type silicon semiconductor substrate beneath the first electrode film 5, and electrons are generated by the incident light passing through the first electrode film 5, and accumulated (see FIG. 5, t=t1). At t=t2, when a high bias (a second gate voltage (10 V)) is applied to the first electrode film 5, a high electric field region is formed beneath the first electrode film 5, and the electrons in the accumulation well are ionized by collision, and pairs of electron and hole are formed. Only the electrons are collected in the accumulation well, and the charge is amplified. The holes flow to the interface side of the p type silicon substrate, and contribute nothing to the amplifying function. Later at t=t3, the voltage applied to the first electrode film 5 is returned to the first gate voltage (2 V).

In the example in FIG. 5, application of a first gate voltage and application of a second gate voltage are repeated five times. Every time the second gate voltage is applied, electrons are ionized by collision, the electrons are amplified on each occasion. That is, the amplification factor can be controlled by adjusting the number of times of repetition of application of a first gate voltage and application of a second gate voltage.

Moreover, as clear from FIG. 4, the amplification factor can be controlled by adjusting the ratio of the first gate voltage and second gate voltage.

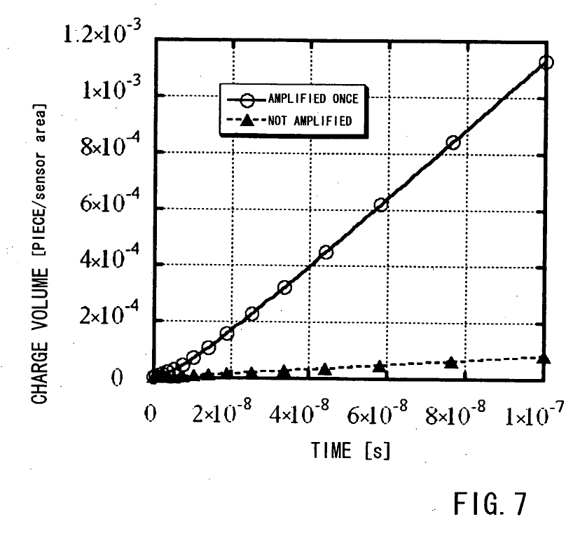

FIG. 7 shows simulation results when amplified once and when not amplified, in the case of constant illumination with light of wavelength of 550 nm and light intensity of 1×10⁻⁸ W/cm², in a charge accumulating and amplifying area of 25×10⁻⁸ cm². By amplifying, 0.1 μs later, the amplification factor becomes 14.

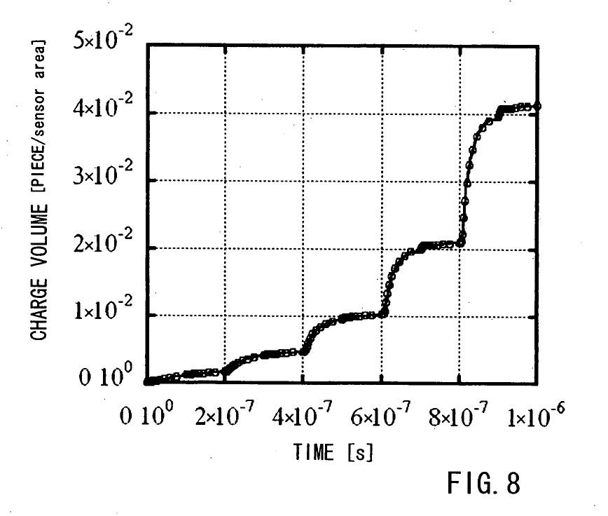

FIG. 8 shows simulation results when amplified five times, in the case of constant illumination with light of wavelength of 550 nm and light intensity of 1×10⁻⁸ W/cm², in a charge accumulating and amplifying area of 25×10⁻⁸ cm². As a result, the amplification factor can be changed by the number of times of amplification.

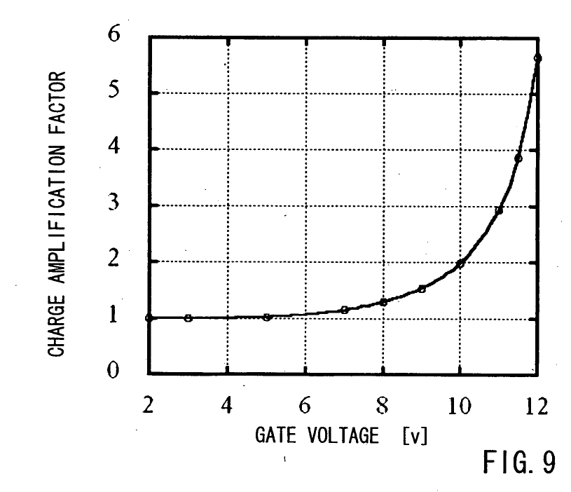

FIG. 9 shows the relation of the charge amplification factor of the device of the embodiment and the second gate voltage (axis of abscissas). The charge amplification factor indicates the increasing rate of electrons or holes, and the first gate voltage is 2 V. From the results in FIG. 9, it is confirmed that the amplification factor can be also controlled by the second gate voltage (axis of abscissas).

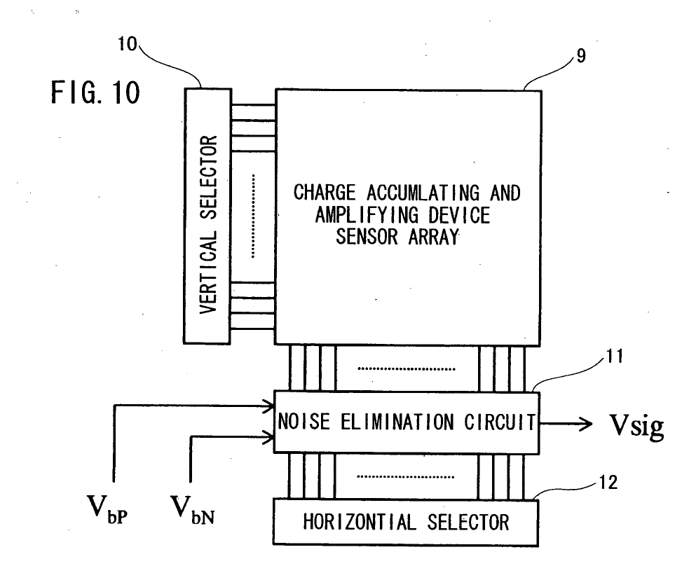

FIG. 10 is a block diagram of a CMOS image sensor having the charge accumulating and amplifying device of FIG. 1 provided in each pixel. In the diagram, reference numeral 9 is a sensor array, 10 is a vertical selector (V. Scanner), 11 is a noise eliminating circuit (Column CDS), and 12 is a horizontal selector (H. Scanner). The vertical selector 10 or the horizontal selector 12 is connected to the electrode 4 in FIG. 1. Vsig is a light signal output. Vbn, Vbp are low current driving biases.

### Embodiment 2

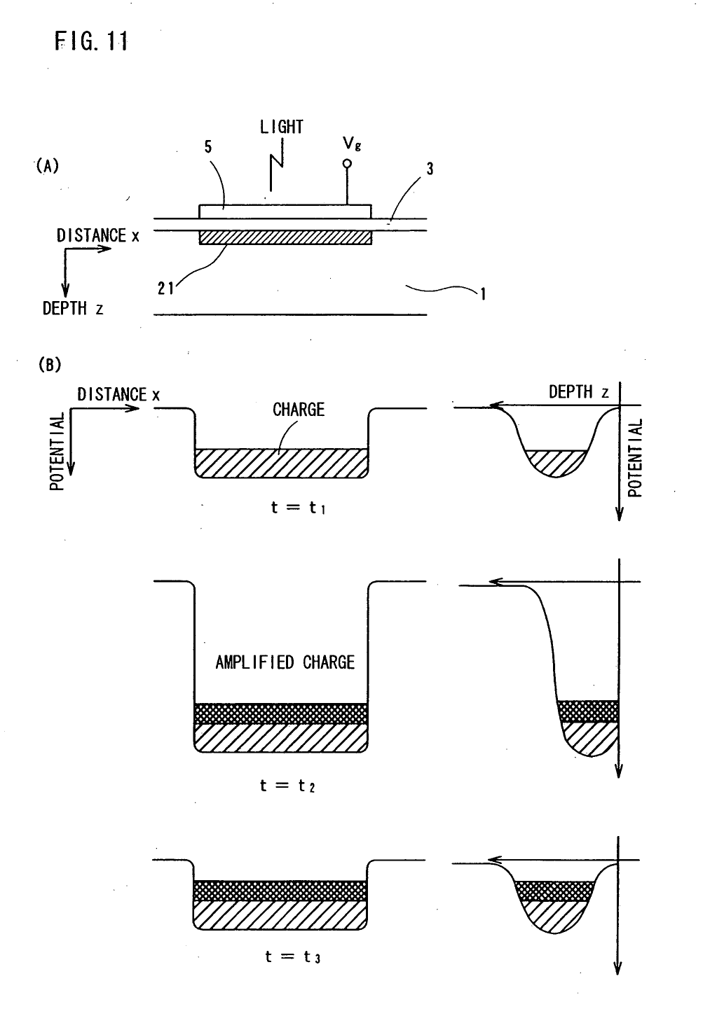

FIG. 11(A) is a sectional view of a charge accumulating and amplifying device in other embodiment of the invention. Same elements as in FIG. 6 are identified with same reference numerals, and their description is omitted.

On the p type silicon substrate 1, an n type impurity is doped near the surface to form a dope region 21. In the embodiment, the p type impurity concentration of the substrate or the accumulation well layer was 1×10¹⁶ cm⁻³, and phosphorus was doped at a concentration of 1×10¹⁷ cm³ as an n type impurity. The doping method was an ion implantation method. The ion implantation flight was 250 nm, and the junction depth was 500 nm.

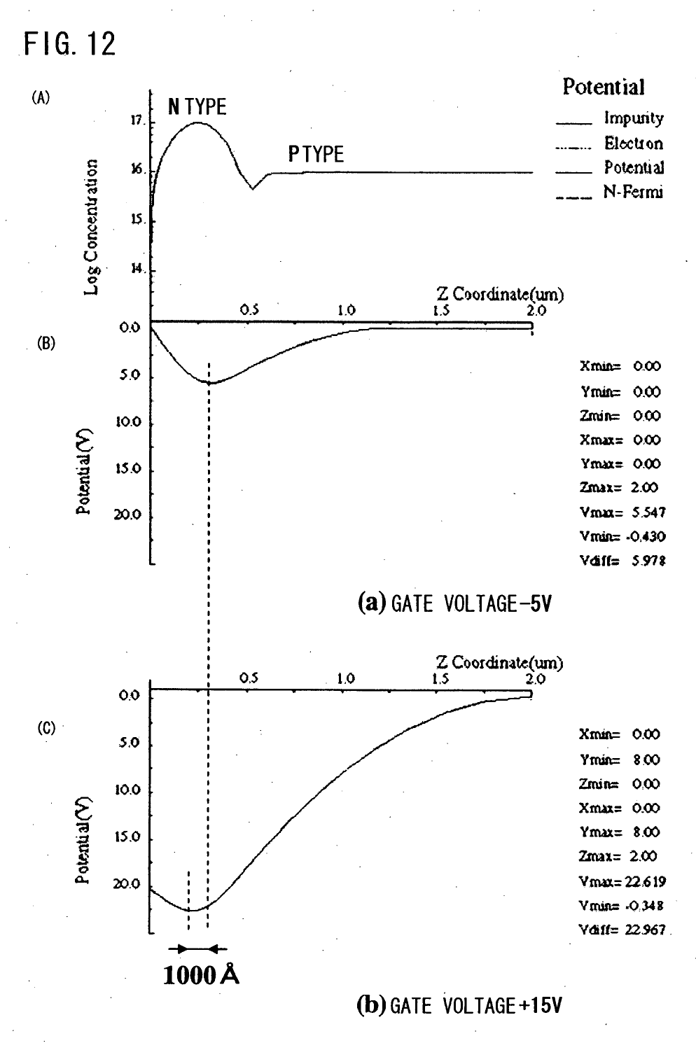

The impurity was doped in the accumulation well layer at the impurity concentration shown in FIG. 12(A). FIG. 12(B) shows the potential distribution (a gate voltage: 5 V) of the accumulation well layer. FIG. 12(C) shows the potential distribution when the gate voltage was elevated to 12 V.

By comparison between FIG. 12(B) and FIG. 12(C), when the voltage is changed, it is known that the bottom of the potential well moved to the depth direction (in the lateral direction in the graph). Since the charge is collected in the potential well, it is known that voltage change, that is, change in the electric field applied to the well leads to move toward the depth direction. In this embodiment, when the electric field increases, the charge moves to the surface direction of the well.

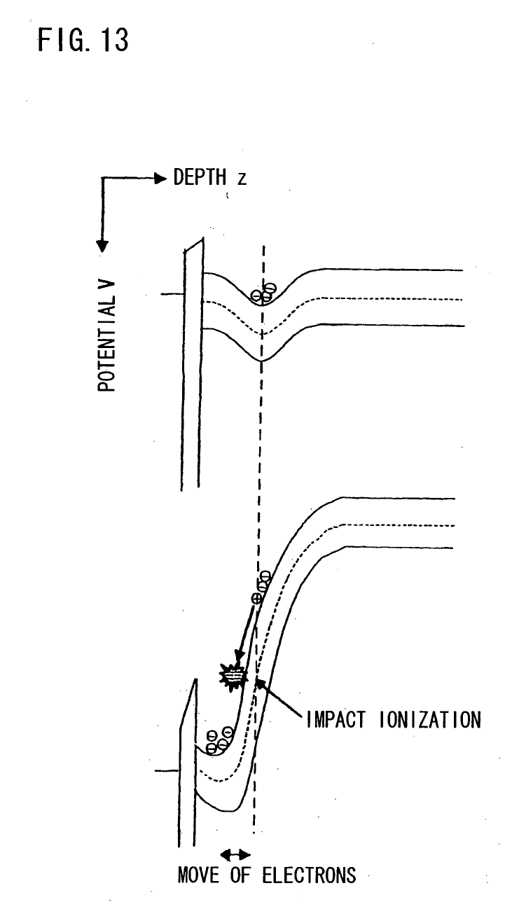

FIG. 13 schematically shows the move of the charge.

Herein, impact ionization refers to a phenomenon of electrons (or holes) accelerated in the high electric field colliding against the lattice to generate electrons (or holes) newly.

FIG. 11(B) is a diagram of a potential distribution in lateral direction (X direction) and depth direction (Z direction) in an accumulation well immediately beneath the first electrode film 5 in the charge accumulating and amplifying device.

On the substrate 1, an accumulation well biased by direct current at a first gate voltage (5 V) is formed, a charge (electron) is generated by the incident light passing through the first electrode film 5, and the charge is accumulated in the accumulation well (t=t1). Since an n type impurity 21 is doped in the p type silicon substrate 1, the location of charge (distance in substrate depth direction) is located at a deeper position than the substrate surface.

When a second gate voltage (12 V) is applied (t=t2), a high electric field is formed immediately beneath the first electrode film 5, the charge in the accumulation well is ionized by collision, pairs of electron and hole are generated, and the electrons are collected in the accumulation well.

By this electric field, the electric charge existing near the substrate surface physically moves to the surface side, collides against the lattice forming the accumulation well, and amplification of the charge is increased.

Afterwards, the voltage applied to the first electrode film 5 is returned to the first gate voltage (t=t3), further the second gate voltage is applied, and the charge can be amplified repeatedly.

In this way, by doping an impurity different from the substrate and changing the applied voltage, the electron collision ionization occurs to amplify the charge, the physical position of the charge moves to the surface direction, the charge collides against the lattice, and hence the charge can be amplified.

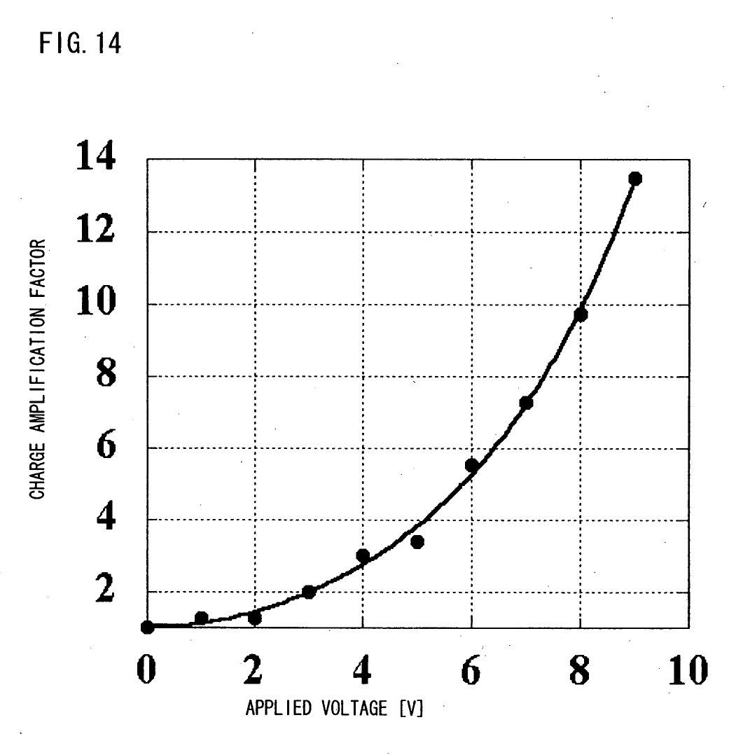

FIG. 14 shows the relation between the charge amplification factor and the applied voltage. As compared with FIG. 9 showing a similar relation in Embodiment 1, in this embodiment, the charge amplifying effect is recognized by a smaller voltage change. Hence, it is known that the charge amplification factor is enhanced.

The invention is not limited to the illustrated embodiments and examples alone, but includes other changes and modifications within a scope not departing from the true spirit of the invention and in a range easily conceived by those skilled in the art.

1. A charge accumulating and amplifying device comprising:
a semiconductor substrate,
a first electrode film formed on the semiconductor substrate being intervened an insulating film between the first electrode file and semiconductor substrate, for transmitting incident light and receiving a gate voltage,
a second electrode film adjacent to the first electrode film, and
a diffusion layer adjacent to the second electrode film,
wherein a charge generated by the incident light is accumulated in a charge accumulation well in the semiconductor substrate beneath the first electrode film when the gate voltage applied to the first electrode film is a first gate voltage, after the charge is accumulated in the accumulation well layer, the accumulated charge having the gate voltage as a second gate voltage is amplified.

2. The charge accumulating and amplifying device of claim 1, wherein the charge moves physically in the charge accumulation well layer.

3. The charge accumulating and amplifying device of claim 2, wherein the charge moves to the surface direction of the substrate.

4. The charge accumulating and amplifying device of claim 1, wherein the surface of the charge accumulation well layer is doped with an impurity of a conductive type different from the conductive type of the semiconductor substrate.

5. The charge accumulating and amplifying device of claim 1, wherein the amplification factor of charge is adjusted by adjusting the ratio of the first gate voltage and second gate voltage.

6. The charge accumulating and amplifying device of claim 1, wherein the amplification factor of charge is adjusted by adjusting the number of times of repeated applications of the first gate voltage and the second gate voltage.

7. The charge accumulating and amplifying device of claim 1, wherein the semiconductor substrate is a p type silicon semiconductor substrate, and the diffusion layer is an n+ type diffusion layer.

8. The charge accumulating and amplifying device of claim 1, wherein the first electrode layer receiving the gate voltage is formed of a polycrystalline silicon doped with an impurity.

9. The charge accumulating and amplifying device of claim 1, wherein by lowering the voltage applied to the second electrode film, the charge in the charge accumulation well layer is transferred to the diffusion layer, and can be read out from the diffusion layer.

10. An image sensor capable of amplifying the charge in each pixel, using a charge accumulating and amplifying device of claim 1 as a pixel.

11. An image sensor having a charge generated in one pixel accumulated in an accumulation well layer corresponding to the pixel, and having the charge in the accumulation well layer being directly read out and signal-processed,
wherein after the charge is accumulated in the accumulation well layer, the electric field applied to the accumulation well layer is changed from the electric field applied to the accumulation well layer at the time of accumulation of the charge, and the charge accumulated in the accumulation well layer is ionized by collision.

12. The image sensor of claim 11, wherein the charge existing at a deeper position than the surface of the accumulation well layer moves to the surface direction of the accumulation well layer on the basis of the change in the electric field, and collision ionization of the charge is induced.

13. The image sensor of claim 12, wherein a doped region doped with an impurity of a conductive type different from the conductive type of the substrate composing the accumulation well layer is formed in the accumulation well layer, and the charge is located at a deeper position than the surface of the accumulation well layer.

14. A semiconductor device having an accumulation well layer of charge,
wherein after the charge is accumulated in the accumulation well layer, the electric field applied to the accumulation well layer is changed from the electric field applied to the accumulation well layer at the time of accumulation of the charge, and the charge accumulated in the accumulation well layer is amplified.

15. The semiconductor device of claim 14, wherein by moving the charge existing at a deeper position than the surface of the accumulation well layer to the surface direction of the accumulation well layer on the basis of the change in the charge, the charge is ionized by collision and is amplified.

16. The semiconductor device of claim 15, wherein a doped region doped with an impurity of a conductive type different from the conductive type of the substrate composing the accumulation well layer is formed in the accumulation well layer, and the charge is located at a deeper position than the surface of the accumulation well layer.

17. A driving method of a charge accumulating and amplifying device having:
a semiconductor substrate,
a first electrode film formed on the semiconductor substrate being intervened an insulating film between the first electrode file and semiconductor substrate, for transmitting incident light and receiving a gate voltage,
a second electrode film adjacent to the first electrode film, and
a diffusion layer adjacent to the second electrode film, comprising:
a step of applying a first gate voltage to the first electrode film, and accumulating a charge generated by the incident light in an accumulation well in the semiconductor substrate beneath the first electrode film, and
a step of amplifying the charge in the charge accumulation well, wherein applying a second gate voltage to the first electrode film to deepen the charge accumulation well, moving the charge accumulated in the charge accumulation well to the bottom of the charge accumulation well to induce a collision ionization phenomenon, and thereby amplifying the charge.

18. The driving method of claim 17, wherein the amplification factor of charge is adjusted by adjusting the number of times of repeated applications of the first gate voltage and the second gate voltage.
